(19) United States
(12) Patent Application Publication
(10) Pub. No.: US 2025/0275223 A1
(43) Pub. Date: Aug. 28, 2025

(54) BIPOLAR TRANSISTOR STRUCTURE WITH FERROELECTRIC MATERIAL

(71) Applicant: GlobalFoundries U.S. Inc., Malta, NY (US)

(72) Inventors: Halid Mulaosmanovic, Dresden (DE); Peter Baars, Dresden (DE)

(21) Appl. No.: 18/589,686

(22) Filed: Feb. 28, 2024

(51) Int. Cl. H01L 29/51; H01L 29/10; H01L 29/73

(52) U.S. Cl. CPC H10D 64/689; H10D 10/00; H10D 62/177

(57) ABSTRACT

Embodiments of the disclosure provide a bipolar transistor structure with a ferroelectric material. A structure of the disclosure may include a base over a substrate. The base includes a first portion laterally between an emitter and a collector, and a second portion over the first portion. A ferroelectric spacer is adjacent the second portion of the base. Other structures include a ferroelectric layer over a back gate terminal of a substrate. A base is on the ferroelectric layer. The base includes a first portion laterally between an emitter and a collector, and a second portion over the first portion.

### STATEMENT REGARDING FEDERAL RIGHTS

This invention was made with government support under DARPA T-MUSIC program Agreement No. HR0011-20-3-0002 awarded by the United States Department of Defense. The government has certain rights in the invention.

### BACKGROUND

The present disclosure relates to the composition of bipolar transistor structures.

Technology is at atomic level scaling of certain micro-devices such as logic gates, bipolar transistors, field effect transistors (FETs), and capacitors. Circuit chips with millions of such devices are common. A bipolar transistor includes three regions of alternating conductivity to control current flow between two terminals. The structure of a bipolar transistor defines several of its properties during operation. The width of an intrinsic base is one physical parameter affecting the performance of a bipolar transistor, e.g., conductivity and associated resistive losses. Conventional processing schemes attempt to limit the horizontal width of an intrinsic base by forming bounding materials, e.g., adjacent dielectric material layers, to limit the intrinsic base width. These techniques may be associated with several additional process steps and operations.

### SUMMARY

The illustrative aspects of the present disclosure are designed to solve the problems herein described and/or other problems not discussed.

Embodiments of the disclosure provide structure including: a base over a substrate and including a first portion laterally between an emitter and a collector, and a second portion over the first portion; and a ferroelectric spacer adjacent the second portion of the base.

Other embodiments of the disclosure provide a structure including: a ferroelectric layer over a back gate terminal of a substrate; and a base on the ferroelectric layer and including a first portion laterally between an emitter and a collector, and a second portion over the first portion.

Additional embodiments of the disclosure provide a structure including: a ferroelectric layer over a back gate terminal of a substrate; a base on the ferroelectric layer and including a first portion laterally between an emitter and a collector, and a second portion over the first portion; and a ferroelectric spacer adjacent the second portion of the base.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows a cross-sectional view of a bipolar transistor structure with ferroelectric spacers according to embodiments of the disclosure.

FIG. 2 shows a cross-sectional view of a bipolar transistor structure with ferroelectric spacers that are polarized and non-polarized according to embodiments of the disclosure.

FIG. 3 shows a cross-sectional view of a bipolar transistor structure with a ferroelectric spacer and a non-ferroelectric spacer according to embodiments of the disclosure.

FIG. 4 shows a cross-sectional view of a bipolar transistor structure with ferroelectric spacers and non-ferroelectric spacers according to embodiments of the disclosure.

FIG. 5 shows a cross-sectional view of a bipolar transistor structure with a ferroelectric layer according to embodiments of the disclosure.

FIG. 6 shows a cross-sectional view of a bipolar transistor structure with a ferroelectric layer and ferroelectric spacers according to embodiments of the disclosure.

FIG. 7 shows a cross-sectional view of a bipolar transistor structure a ferroelectric layer and with ferroelectric spacers that are polarized and non-polarized according to embodiments of the disclosure.

FIG. 8 shows a cross-sectional view of a bipolar transistor structure with a ferroelectric layer, a ferroelectric spacer, and a non-ferroelectric spacer according to embodiments of the disclosure.

FIG. 9 shows a cross-sectional view of a bipolar transistor structure with a ferroelectric layer, ferroelectric spacers, and non-ferroelectric spacers according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure provide a bipolar transistor structure with a ferroelectric material. A structure of the disclosure may include a base over a substrate. The base includes a first portion laterally between an emitter and a collector, and a second portion over the first portion. A ferroelectric spacer is adjacent the second portion of the base. The first and second portion of the base may define an intrinsic base of the bipolar transistor, and a third portion of the base over the second portion may be an extrinsic (i.e., more highly doped) base of the bipolar transistor. Other structures include a ferroelectric layer over a back gate terminal of a substrate. A base is on the ferroelectric layer. The base includes a first portion laterally between an emitter and a collector, and a second portion over the first portion.

The ferroelectric spacer and/or ferroelectric layer may be polarized upon the application of a predetermined switching voltage. The predetermined voltage may arise from the composition of the ferroelectric material and may be significantly higher than the operating voltages of the bipolar transistor structure. According to an example, the switching voltage of the ferroelectric layer may be approximately 2.0 volts (V) but the operating voltage for the bipolar transistor may be at most approximately 1.5 V. When polarized, the ferroelectric materials form a depletion region within the electrically active base and/or diode junctions of the transistor. This depletion region is a region subjected to a higher electric field strength than other active regions of the bipolar transistor. These higher electric fields cause electrons therein to be more rapidly swept through the base and collected at the collector terminal of the transistor. Further details of the ferroelectric spacers and/or layers are discussed herein.

Bipolar junction transistor (BJT) structures, such as those in embodiments of the disclosure, operate using multiple “P-N junctions.” The term “P-N” refers to two adjacent materials having different types of conductivity (i.e., P-type and N-type), which may be induced through dopants within the adjacent material(s). A P-N junction, when formed in a device, may operate as a diode. A diode is a two-terminal element, which behaves differently from conductive or insulative materials between two points of electrical contact. Specifically, a diode provides high conductivity from one contact to the other in one voltage bias direction (i.e., the “forward” direction), but provides little to no conductivity in the opposite direction (i.e., the “reverse” direction). In the case of the P-N junction, the orientation of a diode's forward and reverse directions may depend on the type and magnitude of bias applied to the material composition of one or both terminals, affecting the size of the potential barrier. In the case of a junction between two semiconductor materials, the potential barrier will be formed along the interface between the two semiconductor materials.

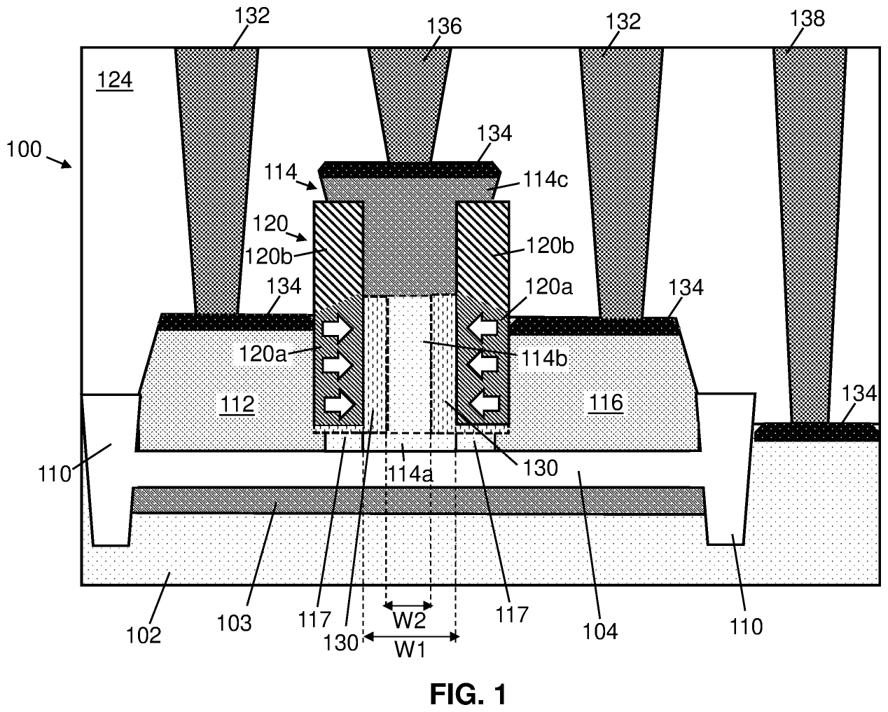

Referring to FIG. 1, a structure 100 according to embodiments of the disclosure is shown. Structure 100 may be on a substrate 102 including, e.g., one or more semiconductor materials. Substrate 102 may include but is not limited to silicon, germanium, silicon germanium (SiGe), silicon carbide (SiC), or any other common IC semiconductor substrates. In the case of SiGe, the germanium concentration in substrate 102 may differ from other SiGe-based structures described herein. A portion or entirety of substrate 102 may be strained, and/or may be doped to any desired polarity or concentration. In addition, some portions of substrate 102 may be doped to provide deep wells, e.g., for other device structures on substrate 102 not explicitly shown or discussed herein. Some portions of substrate 102 may have sufficient doping to provide a back gate terminal 103, e.g., to electrically bias active portions of structure 100 or to polarize an overlying ferroelectric layer as discussed herein.

Structure 100 may include embedded elements for electrically separating active materials formed over substrate 102 from other regions and/or materials. An insulator layer 104 can be above and immediately adjacent to substrate 102. Insulator layer 104 can be, for example, an oxide layer (also referred to herein as a buried oxide (BOX) layer), such as a silicon dioxide layer, or a layer of any other suitable insulator material. Structure 100 also may include one or more trench isolation layers (TI(s)) 110. TI layer(s) 110 may be made by forming and filling trenches (not labeled) with an insulating material such as oxide. TI layer(s) 110 horizontally isolate insulator layer 104 and any components of structure 100 thereon from adjacent regions of material. Various portions of structure 100, including the active semiconductor materials thereof and/or other devices where applicable, may be formed on or above portions of insulator layer 104 that are isolated by TI layer(s) 110. Two TI layers 110 are shown in FIG. 1 as an example, but any number of TI layer(s) 110 may be provided as discussed elsewhere herein to isolate structure 100 from different types of structures and/or components. TI layer(s) 110 may be formed before active materials are formed over substrate 102, but this is not necessarily true in all implementations.

Each TI layer 110 may be formed of any currently-known or later developed substance for providing electrical insulation, and as examples may include: silicon nitride (Si₃N₄), silicon oxide (SiO₂), fluorinated SiO₂ (FSG), hydrogenated silicon oxycarbide (SiCOH), porous SiCOH, boro-phospho-silicate glass (BPSG), silsesquioxanes, carbon (C) doped oxides (i.e., organosilicates) that include atoms of silicon (Si), carbon (C), oxygen (O), and/or hydrogen (H), thermosetting polyarylene ethers, a spin-on silicon-carbon containing polymer material, near frictionless carbon (NFC), or layers thereof.

Structure 100 defines a bipolar transistor, and optionally a heterojunction bipolar transistor (HBT). Structure 100 can be formed on, or otherwise include, active semiconductor material(s) bounded within TI layer(s) 110. Structure 100 in particular can include the three terminals to provide a bipolar transistor: an emitter 112 on insulator layer 104, a base 114 on insulator layer 104 and adjacent emitter 112, and a collector 116 on insulator layer 104 and adjacent base 114. In the configuration shown, base 114 is horizontally between emitter 112 and collector 116.

Emitter 112 and collector 116 each may be formed by epitaxial growth of silicon and/or other semiconductor materials (e.g., silicon germanium (SiGe) or other materials different from substrate 102) on insulator layer 104 and may have a predetermined conductivity (i.e., doping) type, e.g., by being doped in-situ or during formation of semiconductor material over insulator layer 104. Emitter 112 and collector 116 each may be monocrystalline in structure. Structure 100 also may include intrinsic emitter/collector (E/C) regions 117 horizontally between base 114 and emitter 112, and horizontally between base 114 and collector 116. Intrinsic E/C regions 117 may have the same doping type as emitter 112 and collector 116 but in a lower concentration to provide intermediate conductivity between the opposite polarity terminals (e.g., N-P-N doped materials) of structure 100. Intrinsic E/C regions 117 may be formed by controlling the amount of doping and/or dopant diffusion into portions of semiconductor material adjacent emitter 112 and collector 116. Intrinsic E/C regions 117 each may be considered part of an emitter terminal (with emitter 112) or part of a collector terminal (with collector 116) in a bipolar transistor structure.

Base 114 of structure 100 may include various subcomponents, e.g., a first portion 114a and second portion 114b which together define an “intrinsic base.” First portion 114a is a part of base 114 that is horizontally between emitter 112 and collector 116. Second portion 114b may be on first portion 114a, above the upper surfaces of emitter 112 and collector 116. A third portion 114c may be on second portion 114b. Third portion 114c may include a more highly doped “extrinsic base” for the transistor (thus, indicated with different cross-hatching), and may also include a “transition region” having a higher dopant concentration than portions 114a, 114b but less than other areas of third portion 114c. Thus, the boundary between the intrinsic base and extrinsic base regions of base 114 may be coincident with the boundary between second portion 114b, 114c, or it may be in another location within third portion 114c. Second portion 114b, and optionally a lower area of third portion 114c thereon, may be adjacent or between a set of ferroelectric spacers 120. Upper areas of third portion 114c may overlie ferroelectric spacers 120, and optionally may overhang ferroelectric spacers 120 as a result of replacement metal gate (RMG) processing. Base 114 serves to control current flow between emitter 112 and collector 116. First portion 114a and second portion 114b may be p-type doped monocrystalline SiGe, and/or similar semiconductor materials having an opposite conductivity type from emitter 112 and collector 116 but with relatively low amounts of doping. First portion 114a of base 114 may be located on insulator layer 104 above back gate terminal 103. First portion 114a may be formed during any conventional replacement gate process. The doping type of first portion 114a may be adjustable to provide NPN or PNP-conductivity types in a bipolar transistor. Third portion 114c may have the same doping polarity as first portion 114a but with higher dopant concentrations. Second portion 114b and third portion 114c each may be formed by epitaxial growth (including selective or non-selective implementations) of polycrystalline semiconductor in an opening above first portion 114a. Moreover, portions 114b, 114c may be formed together by a single deposition and/or growth process and may be differential based on their relative levels of doping, and/or shapes and/or positions in structure 100.

Structure 100 includes at least one ferroelectric spacer 120 (two shown in FIG. 1) adjacent second portion 114b and third portion 114c of base 114 (i.e., it horizontally abuts portions of the intrinsic base and extrinsic base materials within base 114), and optionally over intrinsic E/C regions 117 and/or an adjacent portion of emitter 112 or collector 116. Each ferroelectric spacer 120 may include one or more dielectric materials that become electrically polarized when a voltage of sufficient magnitude (i.e., a “switching voltage”) is applied thereto. Each ferroelectric layer 120 in structure 100 thus may include a ferroelectric material. A “ferroelectric material” refers to any material exhibiting spontaneous electric polarization oriented in a particular direction. Such materials may include oxide-based dielectric materials and/or other types of dielectric layers suitable for use in a capacitive structure (i.e., between two conductive plates) and/or within a transistor structure beneath a gate metal. Ferroelectric materials may include hafnium oxide (HfO₂), hafnium-zirconium oxide (HZO), and/or other materials having similar properties.

An external electric field of at least a minimum voltage magnitude, i.e., a switching voltage, may be effective to polarize ferroelectric spacer 120 and/or change its direction of polarization. The switching voltage magnitudes indicates a voltage differential across two terminals for polarizing ferroelectric materials therebetween. For instance, ferroelectric spacer(s) 120 may include one or more materials having a switching voltage of two volts (V) may exhibit electric polarization in a first orientation when electrically biased at a differential of +2.0 V or more between two terminals (e.g., between emitter 112 and base 114, or between base 114 and collector 116). Ferroelectric spacer 120 or similar ferroelectric materials may exhibit polarization in the opposite direction or switch from a positive orientation to a negative orientation when electrically biased at a voltage magnitude that exceeds −2.0 V (e.g., between emitter 112 and base 114, or between base 114 and collector 116). In either scenario, one of the two terminals is set to ground (i.e., zero volts) and the other terminal is set to the magnitude of the switching voltage to create the desired voltage differential.

Any material having arrows in one direction in the accompanying FIGS. indicates that this layer of material has been polarized (e.g., in the direction shown). Any material having arrows in multiple directions indicates that the layer of material is not electrically polarized, but there may be no difference in physical composition between polarized and non-polarized material. Positive or negative biasing voltages having a magnitude that is less than the switching voltage (e.g., conventional operating voltages for a bipolar transistor, such as up to approximately +1.50 V or at least approximately −1.50 V) may not affect the electric polarization in ferroelectric spacer(s) 120. The switching voltage, when applied, may only polarize certain ferroelectric materials and/or portions of a ferroelectric material. For example, applying the switching voltage to some terminals and not others, and/or applying an inverted switching voltage to some terminals and not others after programming occurs, may cause only some ferroelectric materials and/or portions thereof to become polarized.

In the example of structure 100 illustrated in FIG. 1, ferroelectric spacers 120 each include a polarized region 120a (e.g., a lower portion of ferroelectric spacer 120 between emitter 112 and base 114 or between collector 116 and base 114) and a non-polarized region 120b on polarized region 120a. The different polarizations in each region 120a, 120b of ferroelectric spacer 120 may arise from, e.g., applying a switching voltage at emitter 112 and collector 116 but not at base 114, thus only polarizing the portions of ferroelectric spacer 120 that are located near emitter 112 and collector 116. Polarized region 120a of ferroelectric spacer 120 may be oriented toward the intrinsic base (e.g., at second portion 114b) of base 114, and thus may create a depletion region 130 within the intrinsic base (e.g., within second portion 114b) within base 114. A “depletion region” refers to a region subjected to a higher electric field, thereby causing electrons therein to be more rapidly through base 114 and collected at collector 116. In structure 100, depletion region 130 appears as a result of forming polarized region(s) 120a within ferroelectric spacer(s) 120, thereby creating depletion region(s) 130 within areas of base 114 that are adjacent polarized region 120a, e.g., second portion 114b of base 114. Depletion region 130 also may extend partially below ferroelectric spacer 120, but the vertical span of depletion region 130 is less significant due to the direction in which ferroelectric spacer 120 is polarized.

In the example shown, emitter 112 and collector 116 are doped N-type and base 114 is doped P-type to provide an “NPN” bipolar transistor structure. Polarized regions 120a of ferroelectric spacer 120 are polarized such that the negative pole is facing away from base 114 and the positive pole is facing toward base 114. As a result, electrons are pulled inward to inner portions of base 114 and out of depletion regions 130. In the case of an opposite polarity (i.e., “PNP”) bipolar transistor, the direction of polarization in polarized regions 120a would be reversed to produce depletion regions 130 (by pulling holes into depletion region 130).

During operation, depletion regions 130 functionally reduce the horizontal width of the intrinsic base materials of base 114 within second portion 114b. That is, base 114 may have a larger first width W1 (e.g., within second portion 114b) between non-polarized region(s) 120b of ferroelectric spacer(s) 120 but may have a narrower second width W2 (e.g., within second portion 114b) between polarized region(s) 120a of ferroelectric spacer(s) 120. Depletion region(s) 130 thus cause some areas of base 114 to have a reduced base width (i.e., second width W2) without the need of additional or wider spacer materials alongside base 114. The difference between first width W1 and second width W2 may be electrically significant, e.g., second width W2 may be between approximately five and approximately twenty nanometers thinner than first width W1. The reduced width of base 114 produced from depletion regions 130, among other benefits, increases the maximum operating frequencies of the transistor by reducing the transit time of the charge carriers through base 114.

Base 114 and ferroelectric spacer(s) 120 may be formed by replacement metal gate (RMG) techniques similar to those used for field effect transistors (FETs). Various gate structures (e.g., dummy gates) may be formed on a semiconductor layer (e.g., portions of emitter 112 and collector 116 before further epitaxial growth to form these structures). Ferroelectric spacers 120 are then formed alongside on the gate dummy structure(s), and one or more of the gate structures may be removed and replaced with doped semiconductor material to provide base 114. Thereafter, emitter 112 and collector 116 can be formed adjacent exterior sidewalls of ferroelectric spacers 120 by epitaxial growth on opposite sides of ferroelectric spacers 120. However formed, emitter 112 and collector 116 may be doped, e.g., by in-situ doping and/or doping during formation of semiconductor material. According to an example, emitter 112 and collector 116 may have the same doping polarity as back gate terminal 103, e.g., they each may have n-type doping. It is understood that localized implants and/or dopant diffusion from subsequent anneal steps may result in dopants of the same type as emitter 112 and collector 116 also being in portions of back gate terminal 103. Emitter 112 and collector 116 optionally may have a different composition (e.g., silicon germanium (SiGe)) relative to back gate terminal 103.

In addition to providing electrical insulation, ferroelectric spacer(s) 120 may affect the shape of base 114 over substrate 102. For instance, base 114 may be substantially T-shaped, e.g., first portion 114a may be between intrinsic E/C regions 117, second portion 114b and part of third portion 114c may be horizontally between (e.g., physically constrained by) ferroelectric spacer(s) 120, whereas overlaying parts of third portion 114c extend horizontally over (and thus may overhang) ferroelectric spacer(s) 120. In further implementations, base material 114 may have any of a variety of structural configurations that are not T-shaped. Portion(s) 114a, 114b of base 114 simply may be horizontally thinner or thicker than third portion 114c. The position and size of ferroelectric spacer(s) 120 may be controlled during processing to further affect the size and shape of base 114. It is understood that base 114 may be formed to have other geometries (e.g., shapes other than a “T”) by changing the shape or position of ferroelectric spacer(s) 120.

Structure 100 may include an inter-level dielectric (ILD) layer 124 over insulator layer 104, TI layer(s) 110, and any other components thereon. ILD layer 124 may include the same insulating material as insulator layer 104 or may include a different electrically insulative material for vertically separating active materials from overlying materials, e.g., various horizontally extending wires or vias. ILD layer 124 and insulator layer 104 nonetheless constitute different components, e.g., due to insulator layer 104 being vertically between back gate terminal 103 and the various active components of structure 100. ILD layer 124 may be formed by deposition and/or other techniques to provide electrically insulating materials, and can then be planarized (e.g., using CMP), such that its upper surface remains above any active components formed on substrate 102.

A set of emitter/collector (E/C) contacts 132 through ILD layer 124 may provide the vertical electrical coupling between emitter 112 or collector 116 and overlying metal wires and/or vias. Some portions of emitter 112 or collector 116 may be converted into a silicide layer 134 to improve conductivity between each E/C contact 132 and emitter 112 or collector 116 thereunder, e.g., by providing a conductive metal such as cobalt (Co), titanium (Ti), nickel (Ni), platinum (Pt), or similar material on the upper surface(s) of a targeted material. The conductive material(s) may be annealed while in contact with the underlying semiconductor to produce silicide layer 134 for electrically coupling semiconductor materials to any contacts formed thereon. Excess conductive material can then be removed using any now known or later developed solution, e.g., etching.

Base 114 (e.g., third portion 114c thereof) also may include silicide layer 134 thereon for stronger coupling to a base contact 136 that extends vertically through ILD layer 124. Silicide layer 134 on base 114 may be formed by the same process, or in the same stage of processing, as other materials having silicide layer 134 discussed herein. Further coupling of structure 100 to external components may be provided through a back gate contact 138 that extends through ILD layer 124 to a portion of substrate 102 outside TI layer(s) 110. Such portions of substrate 102 also may include silicide layer 134 thereon. Back gate contact 138 may be coupled to back gate terminal 103 through substrate 102, and thus may electrically bias back gate terminal 103 during operation. In further embodiments discussed herein, other ferroelectric substances may be on back gate terminal 103 and thus back gate contact 138 is capable of polarizing or depolarizing such substances.

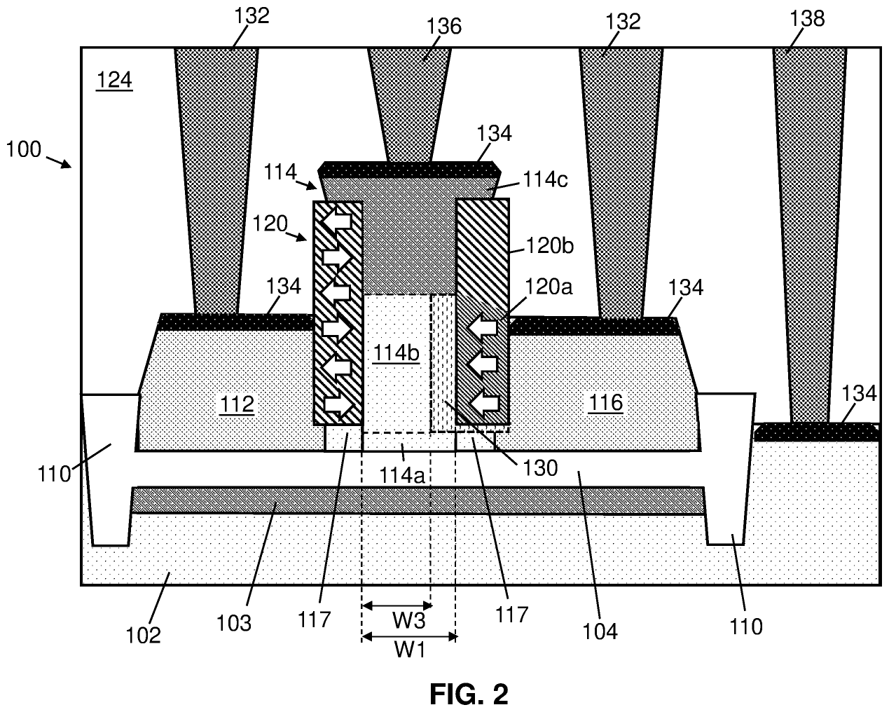

Turning to FIG. 2, further implementations of structure 100 may enable polarizing of only one ferroelectric spacer 120 to form polarized region 120a and non-polarized region 120b, but without forming such regions in another ferroelectric spacer 120 that is also adjacent base 114. Polarizing only one ferroelectric spacer 120 may include, e.g., applying the switching voltage to collector 116 in structure 100 without also applying the switching voltage to base 114 and emitter 112, thus polarizing the lower portion of only one ferroelectric spacer 120. To polarize the other ferroelectric spacer 120, the switching voltage may be applied to emitter 112 without being applied to base 114 and collector 116. FIG. 2 illustrates an example where the switching voltage is applied from base 114 to collector 116. It is understood that the configuration of ferroelectric spacers 120 will be horizontally reversed where the switching voltage is applied from base 114 to emitter 112 without also being applied to collector 116. In this case, only one depletion region 130 may be formed in second portion 114b of base 114, due to polarized region 120a being formed in only one ferroelectric spacer 120. As a result, portions of base 114 adjacent polarized region 120a may have a third width W3 that is less than first width of base 114 adjacent non-polarized region 120b. Third width W3, however, may be larger than second width W2 (FIG. 1) discussed elsewhere herein. Polarizing only one ferroelectric spacer 120 thus provides a lower reduction in base width during operation, but without any modifying of structure 100 itself. Thus, the embodiments of structure 100 shown in FIG. 1 and FIG. 2 may be the same structure, subjected to different switching voltages to provide different base widths. It is understood that the size of depletion regions 130, and hence adjacent active portions of base 114, can be further customized by adjusting the switching voltage(s) applied to structure 100.

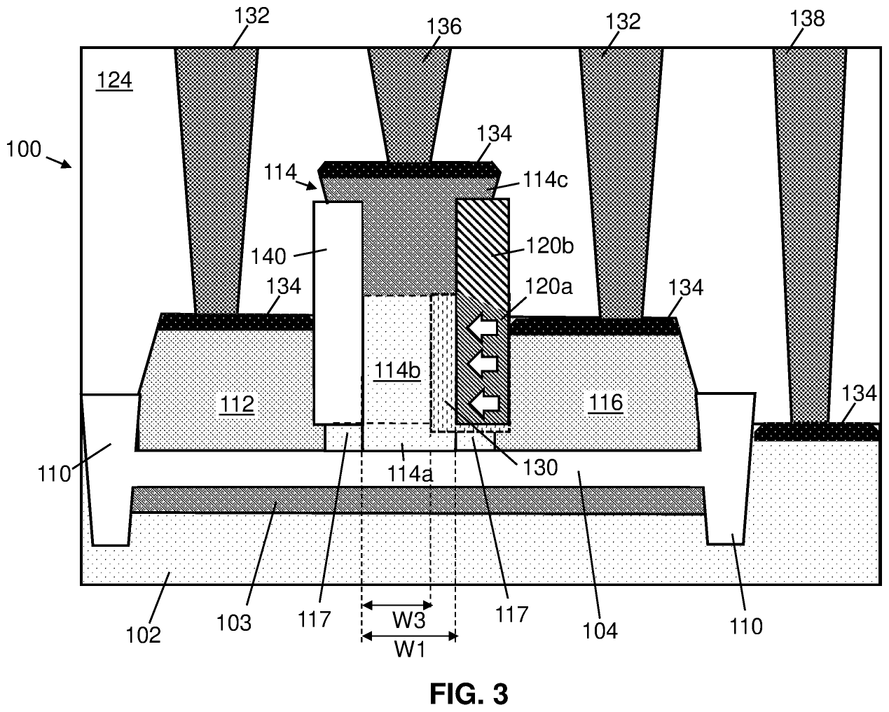

FIG. 3 depicts a further embodiment of structure 100 in which a non-ferroelectric spacer 140 is provided in place of one ferroelectric spacer 120. Non-ferroelectric spacer 140 may include any currently known or later developed insulative material capable of being formed alongside a dummy gate, and remaining alongside base 114, during RMG processing. Such non-ferroelectric materials suitable for non-ferroelectric spacer 140 may include, e.g., silicon nitride (SiN) or other nitride-based insulators. Non-ferroelectric spacer 140, however embodied, may include any currently known or later developed dielectric material. In some applications, non-ferroelectric spacer 140 may have a dielectric constant that is less than the dielectric constant of ferroelectric spacer 120. For instance, where ferroelectric spacer 120 includes HZO, non-ferroelectric spacer 140 may include a material having a lower dielectric constant than HZO (e.g., SiN as discussed herein). However, non-ferroelectric spacer 140 may have an unconstrained dielectric constant in certain applications.

Non-ferroelectric spacer 140 may be of approximately the same size as ferroelectric spacer 120 but will not become polarized even when a switching voltage is applied to various terminals of structure 100. In this case, structure 100 is asymmetric about base 114 and depletion region 130 can only form on one side of base 114. In all other aspects, ferroelectric spacer 120 may operate similarly or identically to other embodiments to selectively reduce the width of base 114. That is, polarizing of ferroelectric spacer 120 will still produce depletion region 130 where desired in horizontally proximal areas of base 114. However, the polarizing of ferroelectric spacer 120 will not create another depletion region 130 alongside non-ferroelectric spacer 140, and thus the amount of reduction in base width may be limited as compared to other implementations. Non-ferroelectric spacer 140 may be desired where only smaller amounts of base width reduction are desired to meet operational requirements. Non-ferroelectric spacer 140 also may be desirable for deliberate structural and electrical asymmetry of the device, which may be beneficial for some of the applications.

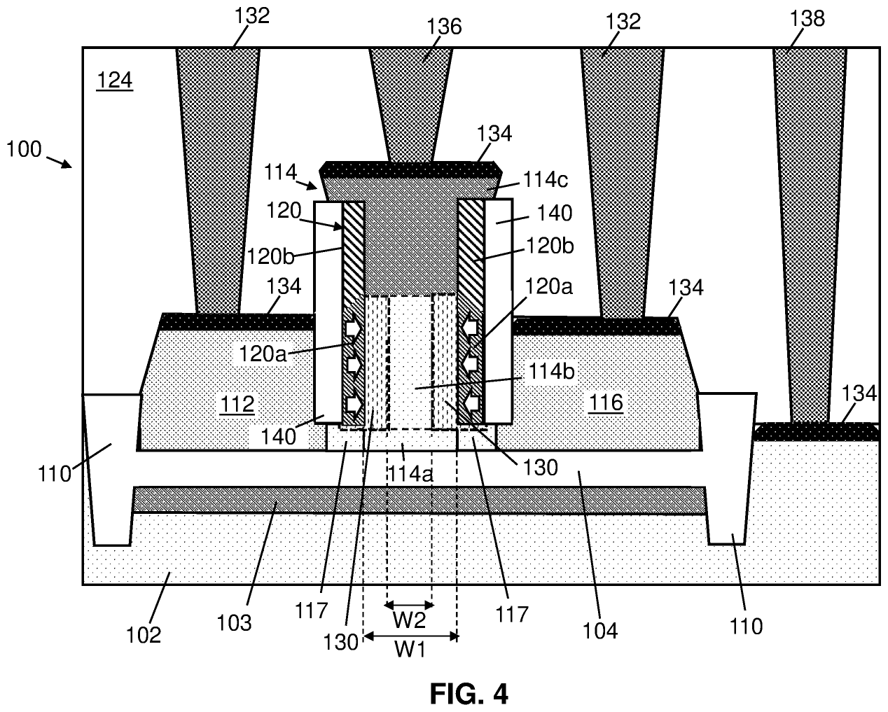

FIG. 4 depicts yet another implementation of structure 100 in which multiple ferroelectric spacers 120 are provided together with multiple non-ferroelectric spacers 140. In this configuration, two ferroelectric spacers 120 are each horizontally adjacent opposing sidewalls of base 114, and each ferroelectric spacer 120 is horizontally adjacent one non-ferroelectric spacer 140. Thus, each ferroelectric spacer 120 is horizontally between base 114 and one non-ferroelectric spacer 140. In this configuration, ferroelectric spacers 120 function as inner spacers and non-ferroelectric spacers 140 function as outer spacers. During operation, applying a switching voltage to collector 112 and/or collector 116 will cause a voltage drop across non-ferroelectric spacer 140 and ferroelectric spacer 120. The amount of voltage on each layer is proportionate to their thicknesses and dielectric constants of the spacer material(s). Non-ferroelectric spacer 140 will not prevent ferroelectric spacer 120 from switching its polarization; the presence of non-ferroelectric spacer 140 instead simply increases the magnitude of the switching voltage needed to polarize ferroelectric spacer(s) 120. Ferroelectric spacers 120, by being adjacent base 114 (e.g., second portion 114b thereof), each may be polarized by applying at least a switching voltage to selected contacts 132, 136 as discussed elsewhere herein. The polarizing of ferroelectric spacers 120 thereby produces depletion region 130 within second portion 114b of base 114.

In this implementation, the presence of non-ferroelectric spacers 140 may limit the horizontal width of ferroelectric spacers 120 in structure 100. The size of second width W2 bounded by depletion regions 130 hence may be larger than in other embodiments of structure 100 that do not include non-ferroelectric spacers 140 with ferroelectric spacers 120. In all other respects, structure 100 may operate similarly or identically to other embodiments described herein (e.g., those shown and discussed with respect to FIGS. 1 and 2) notwithstanding the addition of non-ferroelectric spacers 140. Additionally, it is understood that structure 100 may include ferroelectric spacer 120 adjacent non-ferroelectric spacer 140 on one side of base 114 but may have only ferroelectric spacer 120 or non-ferroelectric spacer 140 on the other side of base 114 to further control the size of depletion region 130 and hence the difference between first width W1 and second width W2.

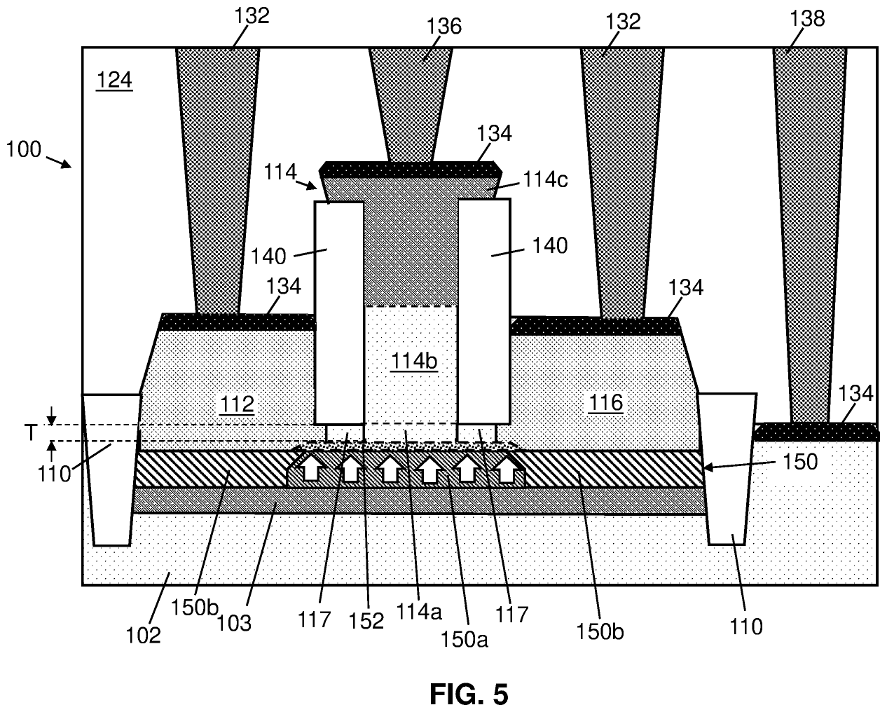

Turning to FIG. 5, further embodiments of structure 100 may include only non-ferroelectric spacers 140 (i.e., they may lack ferroelectric spacers 120 (FIGS. 1-4)) but may include other ferroelectric materials for influencing the available active areas of semiconductor material during operation of a bipolar transistor. For instance, structure 100 may include a ferroelectric layer 150 over back gate terminal 103 (e.g., replacing or included as one layer of a multi-layered buried insulator layer). Ferroelectric layer 150 may be vertically between back gate terminal 103 and the lower surface(s) of emitter 112, base 114, and collector 116. Ferroelectric layer 150 may include any currently known or later developed ferroelectric material, including without limitation any ferroelectric material(s) described herein regarding ferroelectric spacer(s) 120.

Ferroelectric layer 150 may be polarized by applying a switching voltage to base contact 136 and back gate contact 138, e.g., such that only a portion of ferroelectric layer 150 beneath base 114 becomes polarized. In this case, ferroelectric layer 150 may have a polarized region 150a beneath base 114 (and intrinsic E/C regions 117) and non-polarized regions 150b beneath emitter 112 and collector 116. Polarized region 150a may produce an upward-oriented electric field and thus create a depletion region 152 in semiconductor material(s) located over polarized region 150a. Depletion region 152, similar to depletion regions 130 (FIGS. 1-4) discussed elsewhere herein, results from charge carriers migrating upward due to the underlying electric field. Depletion region 152 thus accelerates the collection of electrons from base 114 in collector 116. Depletion region 152 in turn causes a vertical thickness T of intrinsic E/C regions 117 and base 114 beneath non-ferroelectric spacers 140 to be less than the entire vertical span between ferroelectric layer 150 and non-ferroelectric spacer(s) 140 thereover. Thus, the size of the junctions between N-type and P-type doped active semiconductor materials is reduced in comparison to conventional bipolar transistors or other structures 100 that do not include polarized layer 150. Ferroelectric layer 150 enables an operator to control the electrostatics and of the local carrier concentration in base 114 (e.g., within first portion 114a thereof) by ferroelectric polarization in ferroelectric layer 150. This ability can be desirable to tune not only the radio frequency (RF) parameters but also some direct current (DC) operating parameters, e.g., transistor current gain.

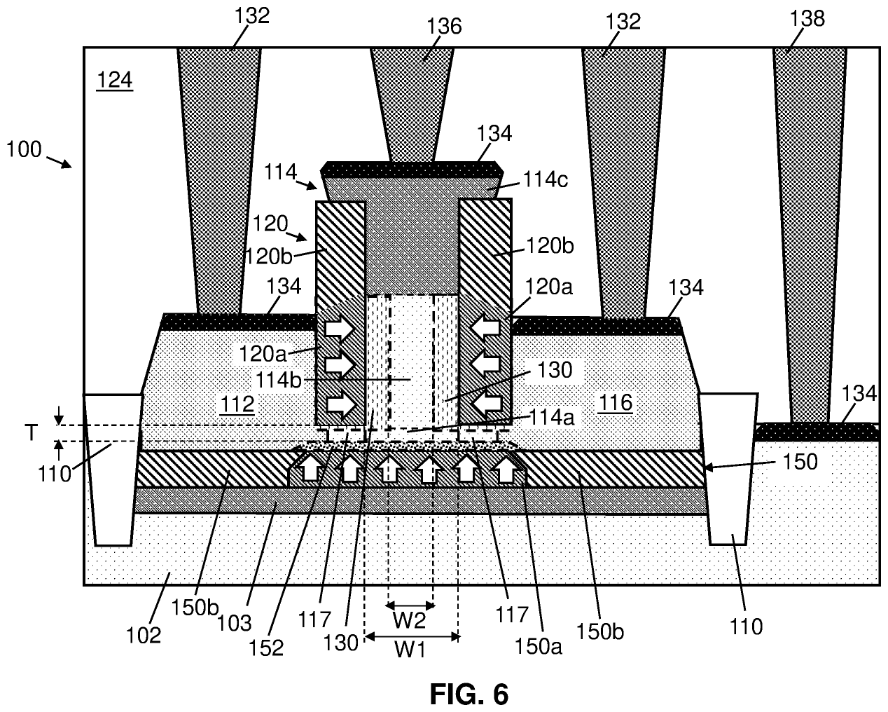

Turning briefly to FIG. 6, embodiments of structure 100 may combine ferroelectric layer 150 with any other implementation of structure 100 having ferroelectric spacers 120 therein. For instance, ferroelectric spacers 120 may be implemented together with ferroelectric layer 150 (i.e., non-ferroelectric spacers 140 (FIGS. 3-5) may be absent). In this case, ferroelectric spacers 120 and ferroelectric layer 150 each may be polarized to create depletion regions 130, 152 in respective portions of structure 100. Ferroelectric spacers 120 may reduce the width of base 114 therebetween (e.g., portions of base 114 adjacent polarized regions 120a exhibit second width W2) and ferroelectric layer 150 may reduce the vertical thickness T of active semiconductor material in intrinsic E/C regions 117 and portions of base 114 thereover.

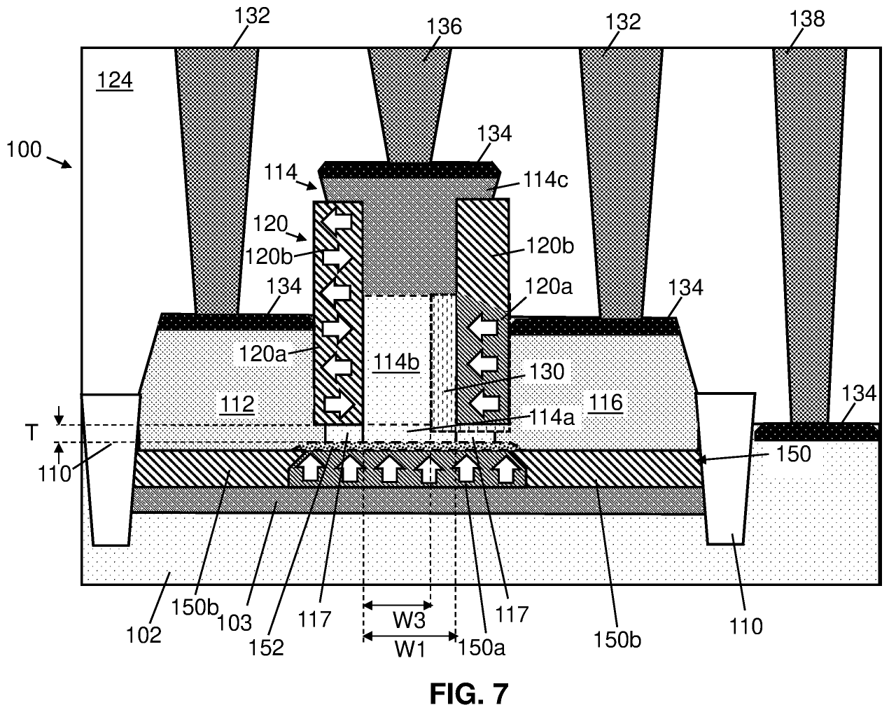

Referring to FIG. 7, only one of ferroelectric spacers 120 and/or ferroelectric layer 150 may be polarized by only applying the switching voltage to selected contacts 132, 136, 138 of structure 100 as discussed herein. FIG. 7 depicts an example of structure 100 with multiple ferroelectric spacers 120 together with ferroelectric layer 150, but in which only one ferroelectric spacer 120 is polarized. Here, the vertical thickness T of active materials in intrinsic E/C regions 117 and overlying portions of base 114 is reduced, but the horizontal thickness of active material in base 114 adjacent polarized region 120a has third width W3 instead of the above noted (smaller) second width W2 (FIG. 6).

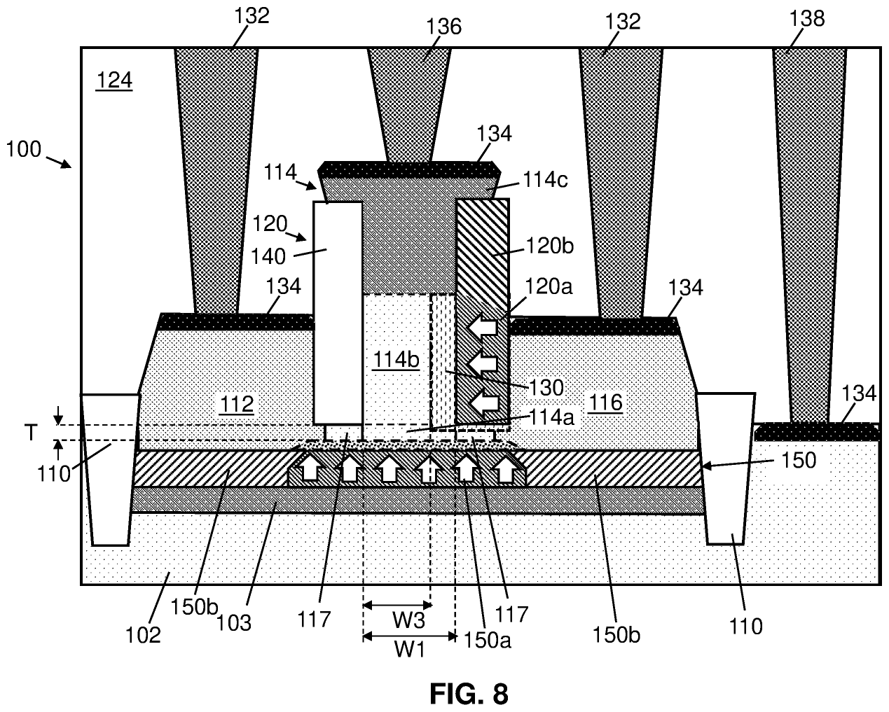

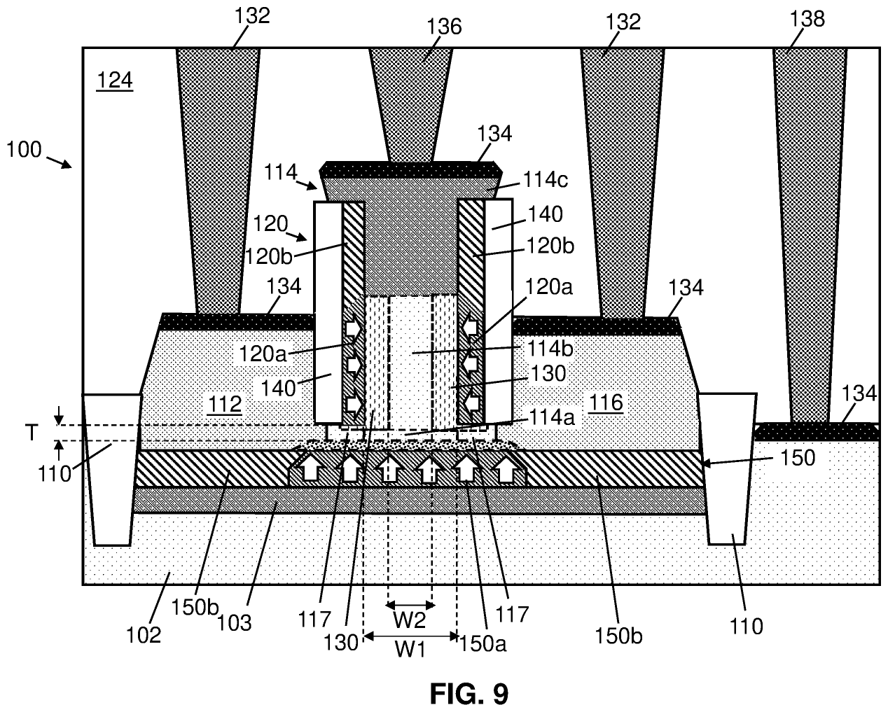

Referring to FIGS. 8 and 9, further embodiments of structure 100 may combine ferroelectric spacers 120 and non-ferroelectric spacers 140 with ferroelectric layer 150. As with other embodiments discussed herein, ferroelectric layer 150 may be polarized to reduce the thickness T of active portions of intrinsic E/C regions 117 and base 114 over polarized region 150a of ferroelectric layer 150. The size of depletion region 152 may not affect the ability to form depletion region(s) 130 in base 114, e.g., ferroelectric spacer(s) 120 may be polarized to affect the size of active regions within base 114. Non-ferroelectric spacer(s) 140 also may be included, e.g., to prevent some depletion regions 130 from being formed in 114 (e.g., as shown in FIG. 8) or to limit the size of depletion regions 130 by limiting the size of ferroelectric spacers 120 (e.g., as shown in FIG. 9). In all other respects, structure 100 may be structurally or operationally similar to other embodiments lacking ferroelectric layer 150. Various embodiments of structure 100 and components thereof can be used together or separately to customize the size of depletion region(s) 130, 152, and hence the operational characteristics of a bipolar transistor.

Embodiments of the disclosure may provide several technical advantages, examples of which are discussed herein. Embodiments of structure 100 allow electrical control over the active area in a bipolar transistor by using ferroelectric materials (e.g., ferroelectric spacer(s) 120 and/or ferroelectric layer(s) 150) to customize the vertical thickness and horizontal width of active semiconductor materials during operation. This control is achievable, e.g., by applying switching voltages to polarize or de-polarize the ferroelectric materials. Among other technical benefits, embodiments of the disclosure may allow bipolar transistors to operate at higher frequencies by accelerating the collection of electrons in collector 116. In addition, embodiments of structure 100 may be manufactured via conventional processes to form a horizontal bipolar transistor and without additional masks. Instead, the composition of one or more spacers, or insulative materials beneath the transistor, may be replaced with ferroelectric materials. Such materials may be electrically polarized, and thus no additional manufacturing steps are required.

The method and structure as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a center processor.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate+/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure comprising:
a base over a substrate and including a first portion laterally between an emitter and a collector, and a second portion over the first portion; and
a ferroelectric spacer adjacent the second portion of the base.

2. The structure of claim 1, wherein the base further includes a third portion on the second portion and adjacent the ferroelectric spacer or over an upper surface of the ferroelectric spacer, the third portion having a higher dopant concentration than the first portion and the second portion of the base.

3. The structure of claim 1, further comprising a non-ferroelectric spacer adjacent the ferroelectric spacer, wherein the ferroelectric spacer is between the second portion of the base and the non-ferroelectric spacer.

4. The structure of claim 1, wherein the ferroelectric spacer includes a polarized region and a non-polarized region on the polarized region.

5. The structure of claim 4, wherein the base further includes a third portion on the second portion, the third portion having a higher dopant concentration than the first portion and the second portion of the base, and the non-polarized region of the ferroelectric spacer is adjacent the third portion.

6. The structure of claim 4, wherein the polarized region of the ferroelectric spacer is on one of the emitter and the collector.

7. The structure of claim 1, further comprising a non-ferroelectric spacer adjacent the second portion of the base, opposite the ferroelectric spacer.

8. The structure of claim 1, further comprising an additional ferroelectric spacer adjacent the second portion of the base, opposite the ferroelectric spacer, wherein the additional ferroelectric spacer does not include a polarized region.

9. A structure comprising:
a ferroelectric layer over a back gate terminal of a substrate; and
a base on the ferroelectric layer and including a first portion laterally between an emitter and a collector, and a second portion over the first portion.

10. The structure of claim 9, further comprising a non-ferroelectric spacer adjacent the second portion of the base.

11. The structure of claim 9, further comprising a ferroelectric spacer adjacent the second portion of the base and above the ferroelectric layer.

12. The structure of claim 11, wherein the base further includes a third portion on the second portion and adjacent the ferroelectric spacer or over an upper surface of the ferroelectric spacer, the third portion having a higher dopant concentration than the first portion and the second portion of the base.

13. The structure of claim 9, wherein the ferroelectric layer includes a polarized region and a non-polarized region adjacent the polarized region.

14. The structure of claim 9, wherein one of the emitter and the collector is over the first portion of the ferroelectric layer, and wherein the base is over the second portion of the ferroelectric layer.

15. A structure comprising:
a ferroelectric layer over a back gate terminal of a substrate;
a base on the ferroelectric layer and including a first portion laterally between an emitter and a collector, and a second portion over the first portion; and
a ferroelectric spacer adjacent the second portion of the base.

16. The structure of claim 15, wherein the base further includes a third portion on the second portion and adjacent the ferroelectric spacer or over an upper surface of the ferroelectric spacer, the third portion having a higher dopant concentration than the first portion and the second portion of the base.

17. The structure of claim 15, wherein the ferroelectric spacer includes a polarized region and a non-polarized region on the polarized region.

18. The structure of claim 17, wherein the first portion of the ferroelectric spacer is on one of the emitter and the collector.

19. The structure of claim 15, further comprising a non-ferroelectric spacer adjacent the ferroelectric spacer, wherein the ferroelectric spacer is between the second portion of the base and the non-ferroelectric spacer.

20. The structure of claim 15, further comprising an additional ferroelectric spacer adjacent the second portion of the base, opposite the ferroelectric spacer, wherein the additional ferroelectric spacer does not include a polarized region.
